(19) United States
(12) Patent Application Publication
(10) Pub. No.: US 2008/0163011 A1
(43) Pub. Date: Jul. 3, 2008

(54) Method and Testing Arrangement for Testing a Device Using 8B/10B Encoding and an 8B/10B Encoder and Decoder

(75) Inventor: Pertti Krans, Haparanda (SE)

Correspondence Address: YOUNG & THOMPSON, 209 Madison Street, Suite 500, ALEXANDRIA, VA, 22314, US

(73) Assignee: ELEKTROBIT SYSTEM TEST OY, OULUNSALO (FI)

(21) Appl. No.: 11/885,115

(22) PCT Filed: Mar. 2, 2006
(86) PCT No.: PCT/FI06/50088

§ 371 Date: Aug. 27, 2007

(30) Foreign Application Priority Data
Mar. 15, 2005 (FI) 20055117

(51) Int. Cl. G01R 31/28; G06F 11/26

(52) U.S. Cl. 714/712; 714/E11.159

(57) ABSTRACT

The invention relates to a method, a testing arrangement, a testing device, an 8B/10B encoder and an 8B/10B decoder, with which the recovery from a 8B/10B encoding error of a device using serial data transmission may be tested. The 8B/10B encoder (302) according to the invention in a transmitting device (30) may create code words unspecified in the ANSI INCITS 203-1994 standard for testing. The 8B/10B decoder (312) in a receiving device (31) is able to indicate having converted a code word unspecified in the ANSI INCITS 203-1994 standard and having entered a testing mode. The testing device (33) connected to the receiving device commences monitoring of the receiving device (31), when the 8B/10B decoder (312) pertaining to it indicates the system having entered the testing mode.

The invention relates to a method and a testing arrangement for testing a device using 8B/10B encoding. The invention also relates to a testing device, an 8B/10B encoder and an 8B/10B decoder utilising the method.

8B/10B encoding is used in data-transmission connections utilising serial data transmission. Especially, high-speed asynchronous data-transmission connections are implemented by means of it. It is commonly used in optical data-transmission networks. In 8B/10B encoding, an 8-bit long code word is converted into a 10-bit code word. After encoding, the converted, parallel 10-bit code word is converted, into serial form which is utilised in the actual data transmission.

8B/10B encoding has two aims. First, in serial data transmission, one wishes to avoid long sequences of ones or zeros which might cause the charging of bus capacitance and a power surge in the input of a device connected to a data-transmission connection. Second, in asynchronous serial data transmission, one must be able to regenerate the clock signal of a transmitting device from a received signal for identifying received bits with great certainty. The regeneration of the clock signal succeeds more definitely, if the receiving device has in its use an adequate number of transitions occurred in transmitted bits from one state to another: from zero to one or vice versa.

The principle of 8B/10B encoding was first presented in the ANSI INCITS 230-1994 standard. In 8B/10B encoding conformable to this standard, for each 8-bit code word there is a counterpart 10-bit code word which always includes from three to eight bit transitions. The encoding table conformable to the standard includes 512 different such 10-bit code words in class D which are used for actual data transmission, when also a so-called disparity bit of the code word is taken into consideration. In addition, 12 different 10-bit control words are specified in the standard in class K which are used in managing a data-transmission connection. Totalled, it is possible to communicate 268 10-bit code words in 8B/10B encoding conformable to the ANSI standard. The remaining 756 code words are incorrect code words in 8B/10B encoding conformable to the standard, unspecified in the standard, which words are not utilised. However, if a receiving device interprets having received an unspecified code word, it may go into a failure mode.

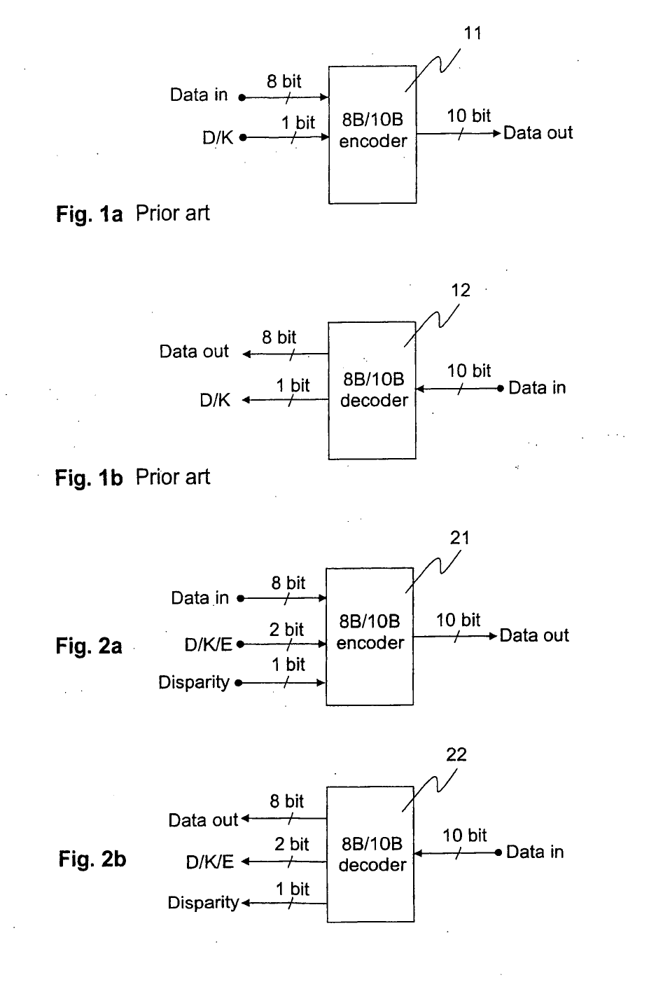

FIG. 1a shows a prior-art 8B/10B encoder 11 of a transmitter of a data-transmission device pertaining in a data-transmission system. The data to be transmitted are brought to the encoder 11 in parallel form (Data in) as 8-bit words. The operation of the encoder 11 is controlled via a D/K input. The state of the D/K input determines if the 10-bit code word (Data out) leaving from the encoder 11 includes actual utility data (D) or control information (K). After the encoder 11, a conversion from parallel to serial form is performed for the data to be transmitted before transmitting the data.

FIG. 1b shows a prior-art 8B/10B decoder 12 of a receiver of a data-transmission device pertaining in a data-transmission system. The serial data to be received come from a data-transmission network and are converted from serial form into parallel form before the 8B/10B decoder. The code word (Data in) to be entered in the 8B/10B decoder comprises 10 bits. The 8B/10B decoder converts the code word it has received comprising 10 bits into a code word comprising 8 bits (Data out). The state of the D/K input of the 8B/10B decoder indicates if the code word converted by the 8B/10B decoder includes actual utility data (D) or control information (K).

Usually the cause of a code word error is in the receiver of the data-transmission device which misinterprets a bit received from the data-transmission network which cannot be identified and corrected by means of error correction. Then, the data-transmission device may interpret having received a code word non-conformable to the standard which may cause a malfunction in the data-transmission device. Because bit errors always occur in reception, the data-transmission device should be able to recover from the failure mode induced by the incorrect code word it has received as soon as possible.

The error tolerance of a data-transmission device in a data transmission system using 8B/10B encoding conformable to the standard may be tested, for example, with methods presented in Annex E of the INCIT 364-2002 standard. A possible testing method alternative is the CJPAT (Continuous Jitter PATtern) method. The CJPAT method tries to test how well the regeneration circuit of the clock frequency of the receiver of a data-transmission device is able to follow great phase jumps induced with the CJPAT method in data to be received.

It is difficult to test malfunctions induced by received incorrect, unspecified code words with 8B/10B encoders according to prior art. This is caused by the fact that the 8B/10B encoders according to prior art do not transmit code words non-conformable to the ANSI standard. Because of this, one has to use correct 8B/10B code words conformable to the standard in testing data-transmission devices. One has to edit code words transmitted in testing after the 8B/10B encoder so that the receiving data-transmission device interprets the code word received non-conformable to the standard. Bits transmitted in the testing method may be edited, for example, with the CJPAT method. This testing method is awkward to implement and its results may be unreliable.

As an extension of 8B/10B encoding, a 16B/20B encoding method has been presented later. In such systems, two 8B/10B encoding devices operate in parallel. The separate operation of both encoding devices corresponds the operation of a conventional 8B/10B encoding device.

The object of the invention is to present a method and a device arrangement for transmitting 8B/10B code words non-conformable to the standard, unspecified in the ANSI INCITS 230-1994 standard, by using which, one is able to test the recovery of a receiving data-transmission device from receiving code words transmitted, non-conformable to the standard in data-transmission systems using 8B/10B encoding.

The objects of the invention are achieved with a device arrangement in which the 8B/10B encoder of the transmitting device is converted in such a way after which the 8B/10B encoder may transmit 8B/10B code words unspecified in the ANSI INCITS 230-1994 standard for performing testing. Correspondingly, the 8B/10B decoder of the receiving device is converted in such a way after which the 8B/10B decoder may indicate having received a code word non-conformable to the standard which is used in testing the recovery of the receiving device. The testing device commences monitoring of the receiving device, when it observes the receiving device having received a code word non-conformable to the standard.

An advantage of the invention is that the error tolerance of a data-transmission device pertaining in a data-transmission system may be tested by transmitting an unspecified 8B/10B code word non-conformable to the standard to the data-transmission device.

A further advantage of the invention is that, in testing, the tester is able to utilise individual test codes non-conformable with the ANSI standard specifiable by the tester or their sequences.

Additionally, an advantage of the invention is that error recovery testings may also be performed in a data-transmission device connected to a data-transmission network.

It is characteristic for a method according to the invention for testing the recovery of a device utilising serial data transmission from a malfunction induced by 8B/10B encoding that in the method
a code word unspecified in the ANSI INCITS 230-1994 standard is created with an 8B/10B encoder of a transmitting device which encoder has been forced to a testing mode
the 8B/10B code word created in the 8B/10B encoder unspecified in the ANSI INCITS 230-1994 standard is transmitted to a receiving device
the receiving device indicates having received the 8B/10B code word unspecified in the ANSI INCITS 230-1994 standard, and that
a testing device monitors the functions of the receiving device, when it has established the receiving device having received the 8B/10B code word unspecified in the ANSI INCITS 230-1994 standard.

It is characteristic for a testing arrangement according to the invention for monitoring the recovery of a device utilising serial data transmission from an 8B/10B code word error that in the testing arrangement
a code word unspecified in the ANSI INCITS 230-1994 standard is arranged to be created with an 8B/10B encoder of a transmitting device which encoder is arranged to be forced to a testing mode for commencing testing
the 8B/10B code word unspecified in the ANSI INCITS 230-1994 standard is arranged to be transmitted to a receiving device
the receiving device is arranged to indicate having received the 8B/10B code word unspecified in the ANSI INCITS 230-1994 standard, and
a testing device is arranged to monitor the functions of the receiving device, when it has established the receiving device having received the 8B/10B code word unspecified in the ANSI INCITS 230-1994 standard.

It is characteristic for a monitoring test device according to the invention of an 8B/10B code word error of a device utilising serial data transmission that the testing device comprises
an interface from the testing device to a D/K/E output of an 8B/10B decoder of a receiving device, and
means for commencing monitoring, if the bipolar D/K/E output of the 8B/10B decoder of the receiving device is in a mode which indicates the receiving device having received an 8B/10B code word unspecified in the ANSI INCITS 230-1994 standard.

It is characteristic for an 8B/10B encoder according to the invention that it comprises a D/K/E input by using which the 8B/10B encoder may be set to a testing mode in which it is arranged to transmit 10-bit code words unspecified in the ANSI INCITS 230-1994 standard.

It is characteristic for an 8B/10B decoder according to the invention that it. comprises a D/K/E output by using which the 8B/10B decoder is arranged to indicate having entered a testing mode in which it is arranged to convert the received code words unspecified in the ANSI INCITS 230-1994 standard into 8-bit code words.

Some advantageous embodiments of the invention are described in the dependent claims.

The basic idea of the invention is the following: To the 8B/10B encoder of a transmitting device conformable to the ANSI INCITS 230-1994 standard is added a control input by using which the 8B/10B encoder conformable to the standard as such is made to transmit also unspecified code words non-conformable to the standard. An 8B/10B encoder according to the invention is achieved by converting the unipolar D/K control input of the 8B/10B encoder into a bipolar control input, whereby by means of this bipolar control input one is able to define if the 8B/10B encoder transmits a code word of class D conformable to the standard, a code word of class K or a code word according to the invention for testing the receiving device. Hereinafter, the code word according to the invention is called a class-E code word.

Correspondingly, the 8B/10B decoder according to the invention of a receiving device differs from the 8B/10B decoder according to prior art in comprising a bipolar D/K/E output, by means of the states of which, one is able to indicate if the received code word is a class-D code word conformable to the standard or a class-K code word or a class-E code word according to the invention utilised in the testing of a receiving data-transmission device.

The invention will now be described in detail. The description refers to the accompanying figures in which

FIG. 1a shows an 8B/10B encoder according to prior art,

FIG. 1b shows an 8B/10B decoder according to prior art,

FIG. 2a shows by way of examples an 8B/10B encoder according to the invention,

FIG. 2b shows by way of examples an 8B/10B decoder according to the invention,

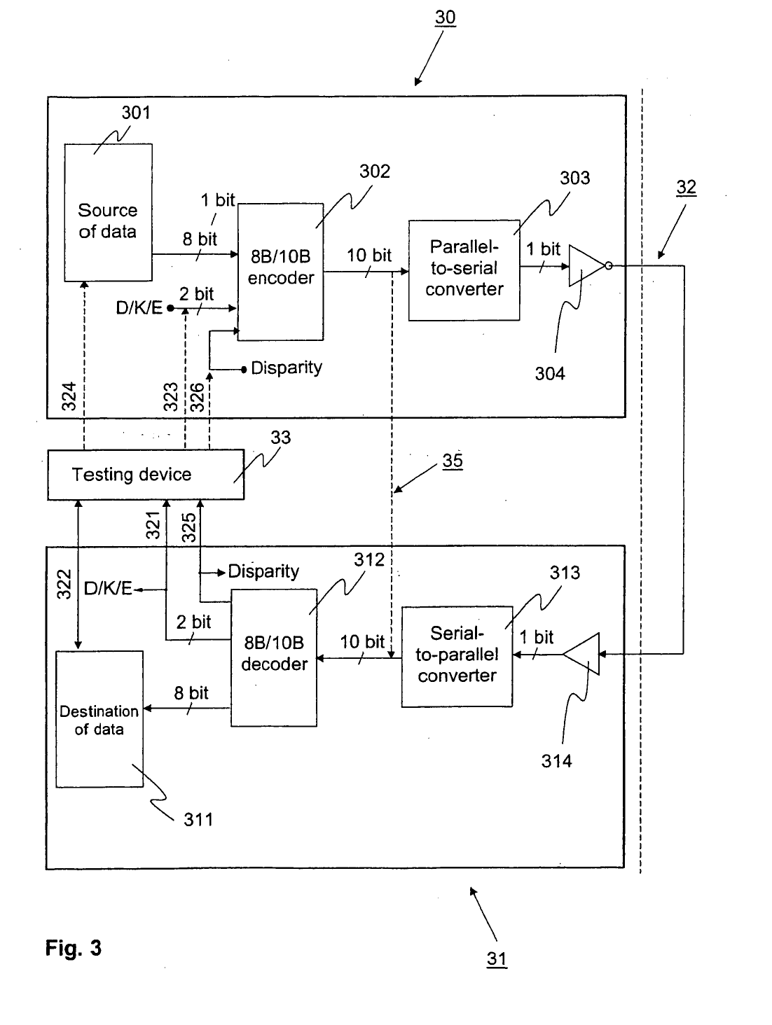

FIG. 3 shows an exemplary testing arrangement for testing the recovering ability from a reception error of a device using serial data transmission, and

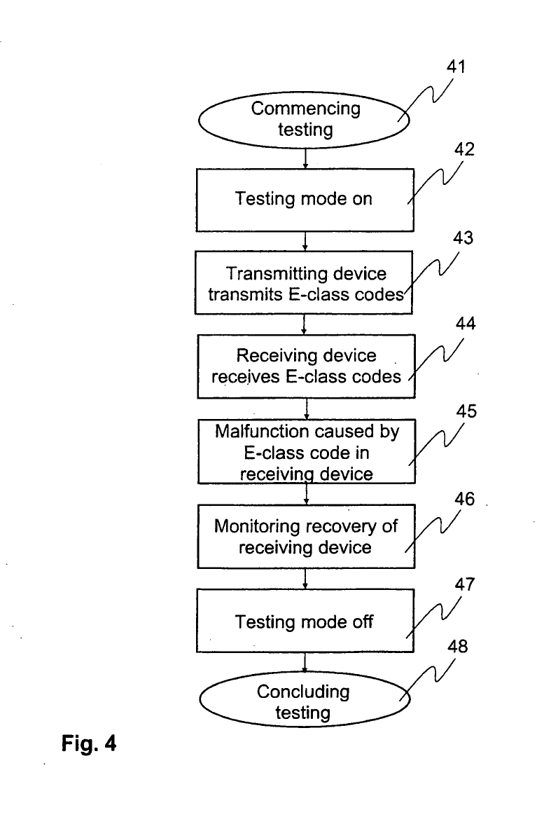

FIG. 4 shows an exemplary flow chart of the principal stages of a testing method in which 8B/10B decoding according to the invention is utilised.

FIGS. 1a and 1b were already described in connection with the description of prior art.

FIG. 2a shows an 8B/10B encoder 21 according to the invention. The mode of the 8B/10B encoder 21 according to the invention is advantageously controlled with a bipolar D/K/E input. A first combination of this input sets the 8B/10B encoder 21 according to the invention into a mode in which it operates according to prior art and it converts and transmits 8-bit utility data entered in the 8B/10B encoder 21 as 10-bit class-D code words. With a second combination of the D/K/E input, the 8B/10B encoder 21 converts and transmits received data as class-K code words according to prior art.

A third combination of the D/K/E input according to the invention guides the 8B/10B encoder 21 into a mode in which it converts and transmits received data as class-E code words according to the invention which are not included in the code words specified in the ANSI INCITS 230-1994 standard. In a receiving device, these class-E code words according to the invention may cause a malfunction the recovery from which may be monitored by means of a testing device connected to the receiving device.

The 8B/10B encoder 21 according to the invention also has a unipolar disparity input which determines parity. By means of it, one may cause a disparity error for testing, even though the code word as such were conformable to the ANSI INCITS 230-1994 standard.

FIG. 2b shows an 8B/10B decoder 22 according to the invention. The mode of the 8B/10B decoder 22 according to the invention is advantageously indicated with a bipolar D/K/E input. A first combination of this output indicates the 8B/10B decoder 22 being in a mode in which it has identified a 10-bit class-D code word conformable to the ANSI INCITS 230-1994 standard which it has converted into 8-bit utility data.

With a second combination of the D/K/E output, the 8B/10B decoder 22 indicates that the code word belongs to class K of the ANSI INCITS 230-1994 standard. The 8B/10B decoder has converted the received 10-bit code word into an 8-bit one.

With a third combination of the D/K/E output, the 8B/10B decoder 22 indicates having received class-E code words according to the invention which are not specified in the ANSI INCITS 230-1994 standard. Then, the converted 8-bit word has been intended for testing the recovering ability from a failure of the receiving data-transmission device. This D/K/E output state is advantageously directed to an appropriate testing device with which one monitors the recovery of the receiving data-transmission device from a malfunction induced by a class-E code word according to the invention.

The 8B/10B decoder 22 according to the invention also has a unipolar disparity output which indicates parity. By means of it, one may indicate a disparity error created for testing, even though the code word as such were conformable to the ANSI INCITS 230-1994 standard.

The operation according to the invention is also possible when using 16B/20B encoding. Then in the transmitter end, two 8B/10B encoders according to the invention are connected in parallel. The D/K/E control inputs of 8B/10B encoders may advantageously be joined together. Correspondingly in the receiver end, two 8B/10B decoders according to the invention operate in parallel the D/K/E outputs of which operate in parallel. One is able to test the receiving device by transmitting an 8B/10B code word non-conformable to the standard with either of the 8B/10B encoders or with both. In the receiver end, the testing mode may be indicated by means of the states of the D/K/E outputs of either 8B/10B decoders or of both. Within the inventive idea, it is also possible to connect more 8B/10B encoders and decoders in parallel than the aforementioned two.

FIG. 3 shows an exemplary testing arrangement which utilises an 8B/10B encoder and decoder according to the invention. The testing arrangement comprises a testing device 33, a transmitting data-transmission device 30, a data-transmission connection 32 which may pertain to an existing data-transmission network, and a receiving data-transmission device 31.

The transmitting data-transmission device 30 includes an 8B/10B encoder 302 according to the invention. It is fed from a source of data 301 in parallel form with 8-bit code words. The operation of the 8B/10B encoder is controlled with its D/K/E input. With it, one chooses if a 10-bit code word converted by the 8B/10B encoder 302 belongs to class D, class K or class E according to the invention. After performing code conversion, the code word is converted into serial form with a parallel-to-serial converter 303. Serial data to be transmitted to the data-transmission network 32 are advantageously transmitted via a bus adapter 304.

The receiving data-transmission device 31 advantageously includes a bus adapter 314 for receiving serial data to be received from the data-transmission connection 32. The received data are converted after the bus adapter with a serial-to-parallel converter 313 into parallel form. After it, the converted 10-bit code word is entered to the 8B/10B decoder 312 according to the invention. The 8B/10B decoder according to the invention converts the code word into an 8-bit one and indicates via the state of the D/K/E output to which code class the converted code word belongs, D, K or E. The converted 8-bit code word is directed to a destination of data 311 utilising data.

If the received code word belongs to class E according to the invention, it causes a malfunction in the destination of data 311 pertaining in the receiving data-transmission device 31. The recovery of the destination of data 311 is advantageously monitored with the testing device 33. The testing device 33 monitors the state of the 8B/10B decoder 312 according to the invention connected to its D/K/E output, designation 321. The operation and recovery of the tested destination of data 311 is advantageously monitored via a connection 322. The connection 322 is advantageously bidirectional, whereby the testing device 33 may also give control commands related to testing for the destination of data 311 if required.

In an advantageous embodiment of the invention, the testing device 33 may also be in data-transmission connection with the transmitting data-transmission device 30 either directly or via the data-transmission connection 32. In the direct connection, the testing device 33 sets the 8B/10B encoder of the data-transmission device transmitting via the connection 323 in a mode via the D/K/E input in which the 8B/10B encoder may transmit class-E code words according to the invention. Via the connection 324, the testing device 33 may advantageously further control the data coming from the source of data to the 8B/10 encoder.

The destination of data being tested, a device utilising 8B/10B encoding, may be, for example, one of the following: a receiver of an optical data-transmission system, an ATM (Asynchronous Transfer Mode) receiver, a device utilising a SCSI (Small Computer System Interface) bus, a device utilising a PCI (Programmable Communication Interface) Express bus, or a base station of a cellular network according to OBSAI (Open Base Station Architecture Initiative) architecture.

The testing according to the invention of one of the aforementioned devices utilising serial data transmission may be performed either in a test jig before installing the device in its operating location, or it is possible to perform testing in a readily installed apparatus, if the transmitting device and the receiving device included in the apparatus are able to utilise the encoding solution according to the invention.

The testing device 33 may primarily be an appropriate testing device according to prior art. However, for performing testing according to the invention, the testing device 33 has to include an interface 321 via which it may be connected to the 8B/10B decoder 312 of the receiving device to examine the state of its D/K/E output. By means of the interface 325, the testing device 33 may also be advantageously connected to the disparity output of the 8B/10B decoder 312. Then, also operation induced by a disparity error included in the code word in the tested device 311 may be monitored.

Advantageously, the testing device 31 also comprises an interface 323 via which it may be connected to the D/K/E input of the 8B/10B encoder 302 of the transmitting device 30 for setting the transmitting device 30 in a testing mode in which it transmits class-E code words according to the invention. By means of an interface 326, the testing device 33 may also be advantageously connected to the disparity input of the 8B/10B encoder 322. Then, also for testing, a disparity error of the code word may be induced, and the operation induced by it in the tested device 311 may be monitored.

In an advantageous embodiment of the invention, the 8B/10B encoder 302 of the transmitting device 30 may be connected with an appropriate parallel bus 35 to the decoder 312 of the receiving device 32. This embodiment is illustrated with a dashed line 35 in FIG. 3. In this embodiment, there is no need to perform to-and-from conversions from parallel to serial form and again back to parallel form.

FIG. 4 shows an exemplary flow chart of the primary stages of testing a device utilising serial data transmission, when one wishes to test the recovery of the device from an error situation induced by a result of 8B/10B decoding. In stage 41, testing is commenced. As a result of it, in stage 42, the 8B/10B encoder of the transmitting device is set in a mode according to the invention in which it may transmit class-E code words which are not specified in the ANSI INCITS 230-1994 standard. This is advantageously done by controlling the 8B/10B encoder to a mode according to the invention via its D/K/E input.

In stage 43, the transmitting device transmits a class-E code or codes according to the invention which the receiving device receives in stage 44. The received class-E code causes a malfunction in the receiving device in stage 45.

In stage 46, the receiving device recovers from the malfunction induced by the class-E code. The recovery of the device is monitored with an external testing device. To the testing device is communicated information on the testing mode of the receiver advantageously via the mode of the D/K/E output of the 8B/10B decoder of the receiving device. The D/K/E output according to the invention is then in a state which indicates the receiving, tested device having received class-E code words. As a result of this, the testing device examines and stores the functions of the receiving device when it tries to recover from the induced error situation.

In stage 47, testing is concluded. Then, the 8B/10B encoder of the transmitting device is controlled via the D/K/E input into a mode in which it only is able to transmit code words according to the ANSI INCITS 230-1994 standard. The 8B/10B decoder according to the invention of the receiving device indicates the change from the testing mode to the normal mode with a change in the state of the D/K/E output. The change in the state of the D/K/E output causes the testing device to conclude the active monitoring of the receiving device and to save data gathered for further processing. After saving, the testing device, the transmitting device and the receiving device have set to their normal mode, stage 48.

Above are described some advantageous embodiments of a method and a device according to the invention. The invention is not limited to the above-described solutions, but it is possible to apply the inventive idea with several ways within the limitations of the claims.

1. A method for testing the recovery from a malfunction of a data-transmission device (31), in which method the malfunction is induced by a received 8B/10B code word unspecified in the ANSI INCITS 230-1994 standard, characterised in that in the method
a code word unspecified in the ANSI INCITS 230-1994 standard is created with an 8B/10B encoder (302) of a transmitting device (30) which encoder has been forced to a testing mode
the 8B/10B code word created in the 8B/10B encoder (302) unspecified in the ANSI INCITS 230-1994 standard is transmitted to a receiving device (31)
the receiving device (31) indicates having received the 8B/10B code word unspecified in the ANSI INCITS 230-1994 standard, and that
a testing device (33) monitors the functions of the receiving device (31), when it has established the receiving device having received the 8B/10B code word unspecified in the ANSI INCITS 230-1994 standard.

2. The method according to claim 1, characterised in that the transmitting device (30) is forced to a testing mode via a bipolar D/K/E control input of the 8B/10B encoder (302) of the transmitting device (30).

3. The method according to claim 1, characterised in that the receiving device (31) indicates having received the 8B/10B code word unspecified in the ANSI INCITS 230-1994 standard with a state of the bipolar D/K/E output of its 8B/10B decoder (312).

4. The method according to claim 3, characterised in that the testing device (33) commences monitoring of the functions of the receiving device (31), when it has established that the D/K/E output of the 8B/10B decoder (312) of the receiving device (31) indicates having received the 8B/10B code word unspecified in the ANSI INCITS 230-1994 standard.

5. The method according to claim 1, characterised in that the transmitting device (30) and the receiving device (31) are interconnected with a serial data-transmission connection (32) via which the 8B/10B code word unspecified in the ANSI INCITS 230-1994 standard used in testing is transmitted.

6. The method according to claim 1, characterised in that the transmitting device (30) and the receiving device (31) are interconnected with a parallel data-transmission connection (35) via which the 8B/10B code word unspecified in the ANSI INCITS 230-1994 standard used in testing is transmitted.

7. The method according to claim 1, characterised in that the data-transmission device (31) uses at least two 8B/10B encoders and two 8B/10B decoders in parallel for implementing a 16B/20B encoding arrangement.

8. A testing arrangement for monitoring the recovery from a failure of a device (31) having received an 8B/10B code word unspecified in the ANSI INCITS 230-1994 standard, which testing arrangement comprises
a transmitting device (30)
a receiving device (31)
a data-transmission connection (32, 35) between the transmitting device (30) and the receiving device (31), and
a testing device (33),
characterised in that
a code word unspecified in the ANSI INCITS 230-1994 standard is arranged to be created with an 8B/10B encoder (302) of the transmitting device (30) which encoder is arranged to be forced to a testing mode for commencing testing
the 8B/10B code word unspecified in the ANSI INCITS 230-1994 standard is arranged to be transmitted to the receiving device (31)
the receiving device (31) is arranged to indicate having received the 8B/10B code word unspecified in the ANSI INCITS 230-1994 standard, and
the testing device (33) is arranged to monitor the functions of the receiving device, when it has established the receiving device (31) having received the 8B/10B code word unspecified in the ANSI INCITS 230-1994 standard.

9. The testing arrangement according to claim 8, characterised in that the transmitting device (30) is arranged to be forced to a testing mode via a bipolar D/K/E control input of the 8B/10B encoder (302) of the transmitting device.

10. The testing arrangement according to claim 8, characterised in that the receiving device (31) is arranged to indicate having received the 8B/10B code word unspecified in the ANSI INCITS 230-1994 standard with a state of the bipolar D/K/E output of its 8B/10B decoder (312).

11. The testing arrangement according to claim 10, characterised in that the testing device (33) is arranged to commence monitoring of the functions of the receiving device (31), when it has established that the D/K/E output of the 8B/10B decoder (312) of the receiving device (31) indicates having received an 8B/10B code word unspecified in the ANSI INCITS 230-1994 standard.

12. The testing arrangement according to claim 10, characterised in that the testing device (33) is arranged to commence monitoring of the functions of the receiving device (31), when it has established that a disparity output of the 8B/10B decoder (312) of the receiving device (31) indicates having received an 8B/10B code word including a disparity error.

13. The testing arrangement according to claim 10, characterised in that the data-transmission connection between the transmitting device (30) and the receiving device (31) is serial (32).

14. The testing arrangement according to claim 10, characterised in that the data-transmission connection between the transmitting device (30) and the receiving device (31) is parallel (35).

15. The testing arrangement according to claim 8, characterised in that the receiving device (31) is one of the following: a receiver of an optical data-transmission system, an ATM receiver, a device utilising a SCSI bus, a device utilising a RapidIO bus, a device utilising a PCI Express bus, or a base station of a cellular network according to OBSAI architecture.

16. The testing arrangement according to claim 8, characterised in that, if the data-transmission device is arranged to utilise 8B/10B encoding using at least two parallel 8B/10B encoders and decoders, the testing device (33) is arranged to monitor the functions of the receiving device, when it has established the receiving device (31) having received the 8B/10B code word unspecified in the ANSI INCITS 230-1994 standard with at least one 8B/10B decoder (312) pertaining in the receiver.

17. A testing device (33) for monitoring the recovery from a failure of a device (31) having received an 8B/10B code word unspecified in the ANSI INCITS 230-1994 standard which testing device comprises
means for connecting to a receiving device (322)
means for commencing testing, and
means for monitoring the receiving device,
characterised in that the testing device further comprises
an interface from the testing device (33) to at least one D/K/E output (321) of an 8B/10B decoder (312) of the receiving device (31), and
means for commencing monitoring, if the bipolar D/K/E output of the 8B/10B decoder (312) of the receiving device (31) is in a state which indicates the receiving device having received an 8B/10B code word unspecified in the ANSI INCITS 230-1994 standard.

18. The testing device (33) according to claim 17, characterised in that it further comprises an interface (325) from the testing device (33) to at least one disparity output (325) of the 8B/10B decoder (312) of the receiving device (31).

19. The testing device (33) according to claim 17, characterised in that it further comprises means (324) for connecting the testing device to a D/K/E input of an 8B/10B encoder (302) of a transmitting device (30) for forcing the transmitting device to a testing mode in which the 8B/10B decoder (312) is arranged to transmit 8B/10B code words unspecified in the ANSI INCITS 230-1994 standard.

20. An 8B/10B encoder (21, 302) creating 10-bit code words conformable to the ANSI INCITS 230-1994 standard, characterised in that it further comprises a D/K/E input by using which the 8B/10B encoder may be set to a testing mode in which it is arranged to transmit 10-bit code words unspecified in the ANSI INCITS 230-1994 standard.

21. The 8B/10B encoder (21, 302) according to claim 20, characterised in that its D/K/E input is bipolar.

22. The 8B/10B encoder (21, 302) according to claim 21, characterised in that with
a first combination of the D/K/E input of the 8B/10B encoder, class-D code words specified in the ANSI INCITS 230-1994 standard are output from the 8B/10B encoder
a second combination of the D/K/E input of the 8B/10B encoder, class-K code words specified in the ANSI INCITS 230-1994 standard are output from the 8B/10B encoder, and that with
a third combination of the D/K/E input of the 8B/10B encoder, code words unspecified in the ANSI INCITS 230-1994 standard for use in testing are output from the 8B/10B encoder.

23. The 8B/10B encoder (21, 302) according to claim 20, characterised in that it further comprises a disparity input for inducing a disparity error.

24. An 8B/10B decoder (22, 312) converting 10-bit code words conformable to the ANSI INCITS 230-1994 standard, characterised in that it further comprises a D/K/E output by using which the 8B/10B decoder is arranged to indicate having entered a testing mode in which it is arranged to convert the received code words unspecified in the ANSI INCITS 230-1994 standard into 8-bit code words.

25. The 8B/10B decoder (21, 312) according to claim 24, characterised in that its D/K/E input is bipolar.

26. The 8B/10B decoder (21, 312) according to claim 25, characterised in that with
a first combination of the D/K/E output of the 8B/10B decoder, class-D code words specified in the ANSI INCITS 230-1994 standard are output from the 8B/10B decoder
a second combination of the D/K/E output of the 8B/10B decoder, class-K code words specified in the ANSI INCITS 230-1994 standard are output from the 8B/10B decoder, and that with
a third combination of the D/K/E output of the 8B/10B decoder, code words unspecified in the ANSI INCITS 230-1994 standard which indicate the 8B/10B decoder having received test code words are output from the 8B/10B decoder.

27. The 8B/10B encoder (22, 312) according to claim 24, characterised in that it further comprises a disparity output for indicating a disparity error.
